(19) United States
(12) Patent Application Publication
(10) Pub. No.: US 2008/0313492 A1
(43) Pub. Date: Dec. 18, 2008

(54) Adjusting a Cooling Device and a Server in Response to a Thermal Event

(76) Inventor: Peter A. Hansen, Cypress, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/107,999

(22) Filed: Apr. 23, 2008

Related U.S. Application Data
(60) Provisional application No. 60/943,401, filed on Jun. 12, 2007.

(51) Int. Cl. G06F 1/32; H05K 7/20; G06F 11/20

(52) U.S. Cl. 714/5; 361/687; 713/320; 714/E11.071

(57) ABSTRACT

In an electronic device enclosure, in response to a thermal event or a power event, an output of a cooling device and an operation of at least one of a plurality of electronic devices are adjusted. The adjustment of the output of the cooling device and operation of the at least one of the electronic devices is according to a policy that considers power consumption of the cooling device and the electronic devices.

### CROSS-REFERENCE TO RELATED APPLICATION

This claims the benefit under 35 U.S.C. §119(e) of U.S. Provisional Application Ser. No. 60/943,401, entitled “Moderating Aggregate Server Speed in a Bladed Environment as a Thermal Response,” filed Jun. 12, 2007, which is hereby incorporated by reference.

### BACKGROUND

For enhanced space efficiency while achieving increased processing power, server enclosures (e.g., cabinets, racks, etc.) capable of receiving multiple servers (e.g., such as in the form of server blades) are used. A server enclosure can have multiple slots or other mounting mechanisms to receive corresponding servers.

Concerns associated with a server enclosure that has a relatively large number of servers include power consumption and elevated temperature. Controllers in some conventional server enclosures simply react to high temperature levels within the server enclosures by increasing speeds of fans used to cool the server enclosures until temperature levels are lowered to below target levels. If higher fan speeds cannot adequately lower temperature levels, then the servers in the server enclosure will simply overheat and shut down, which is a condition that is undesirable since the servers that have shut down will become unavailable and therefore will interfere with enterprise operations.

### BRIEF DESCRIPTION OF THE DRAWINGS

Some embodiments of the invention are described, by way of example, with respect to the following figures:

FIG. 1 is a block diagram of an example arrangement of server enclosure, where at least one of the server enclosures incorporates components according to an embodiment; and

FIG. 2 is a flow diagram of a process of handling a thermal event, according to an embodiment.

### DETAILED DESCRIPTION

In accordance with some embodiments, a technique or mechanism of handling a thermal (or power) event in an electronic device enclosure is provided. An “electronic device enclosure” refers to any structure, such as a cabinet, rack, and so forth, that defines a space to receive multiple electronic devices. Examples of electronic devices include server computers (or simply servers), switch modules, communications modules, storage devices, and so forth.

A “thermal event” refers to the occurrence of a condition in which a temperature level of at least some part of the electronic device enclosure is (or will be) at a level that exceeds a threshold. Exceeding a threshold means that the level is either greater than or less than some predefined amount. For example, some part of the electronic device enclosure may overheat and cause a temperature level to be greater than some temperature threshold (in which case actions would have to taken to allow the temperature level of the corresponding part of the electronic device to fall to a level below the temperature threshold). As another example, a temperature level in a part of the electronic device enclosure may fall below some low temperature threshold, in which case an action can be taken to reduce cooling device output to reduce power consumption.

A “power event” refers to an event in which power consumption has exceeded a power threshold (e.g., greater than or less than the power threshold).

In the ensuing discussion, reference is made to a “server enclosure,” which is an enclosure to receive multiple servers. However, note that the same techniques or similar techniques can be applied to enclosures for other types of electronic devices.

In response to detecting a thermal (or power) event in the server enclosure, an output of a cooling device and an operation of at least one of the servers can be adjusted, such as by a controller within the server enclosure. The adjusting of the output of the cooling device and operation of the at least one of the servers is according to a policy that considers power consumption of the cooling device and the servers. One example of a cooling device is a fan for generating air flow within at least a part of the server enclosure to cool that part of the server enclosure. Another example of a cooling device is a device that can generate a flow of refrigerant through refrigerant conduits to parts of the server enclosure. Yet another example of a cooling device is an air conditioning device that is able to generate cooled air (having temperature less than ambient air) and that includes some type of air blower to create a flow of the cooled air to a part of the server enclosure.

An issue associated with a server enclosure is that the power supply (or power supplies) within the server enclosure is (are) able to produce up to some maximum amount of power. Therefore, processing of thermal or power events should consider such maximum power output of power supply(ies). For example, a policy to be considered by a controller for processing a thermal or power event can attempt to budget more power for servers in the server enclosure while budgeting less for cooling device power. In other words, the policy may attempt to keep the cooling devices operating at less than their respective maximum levels to achieve power savings, where the saved power can be re-deployed to other components of the server enclosure, including the servers.

Moreover, by keeping the cooling devices in the server enclosure at less than their respective maximum levels, some headroom exists to allow outputs of the cooling devices to be increased (e.g., the RPM or revolutions per minute output of fans can be increased) to provide further cooling capability in different parts of the server enclosure, should temperature levels rise in such parts of the server enclosure.

In addition, the policy that governs the controller in responding to a thermal or power event can also specify that the thermal or power event is to be processed by reducing operation of at least one of the servers, where reducing the operation can include any one or more of the following: (1) reducing clock speed of the server; (2) reducing the duty cycle of the server; (2) reducing the number of tasks executed by the server; or (3) otherwise modifying operation of the server such that heat generation of the server is reduced.

The policy can also specify that the thermal or power event is to be processed by increasing the output of cooling devices. The policy considers power consumption of the servers and cooling devices in determining the optimal balance between reducing server operations and cooling device outputs in responding to a thermal or power event.

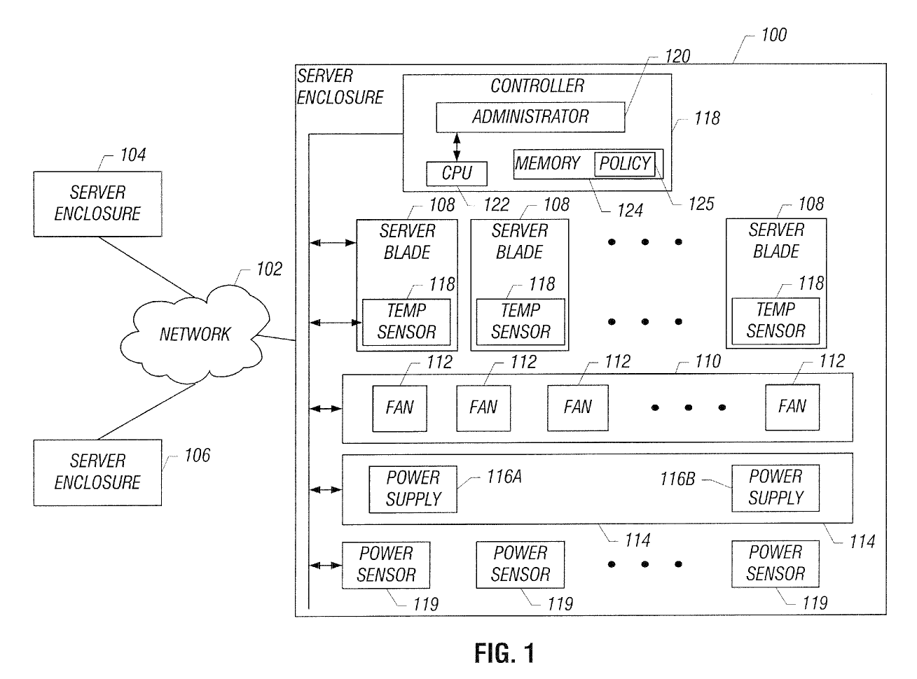

FIG. 1 illustrates example components of a server enclosure 100. Note that the server enclosure 100 can be connected to a data network 102, which is further connected to other server enclosures 104 and 106. The server enclosures 104 and 106 can have similar components as the server enclosure 100, or alternatively, the server enclosures 104 and 106 can have different components.

The server enclosure 100 includes a number of servers 108, which can be in the form of server blades. A server blade includes a thin, modular chassis housing that contains components such as processors, memory, network controllers, and input/output (I/O) components. The server blade provides processing power in a smaller amount of space. The server blades can be mounted in corresponding slots or other mounting mechanisms in the server enclosure 100.

The server enclosure 100 also includes a cooling subsystem 110, which includes a number of fans 112 or other types of cooling devices. The outputs of the fans 112 can be adjusted to provide different levels of cooling. For example, the revolutions per minute (RPMs) of fans can be adjusted to provide different air flow rates to achieve different cooling targets. The server enclosure 100 also includes a power subsystem 114, which can contain one or more power supplies 116A, 116B. In one implementation, the power supplies 116A, 116B are redundant power supplies, where one power supply can take over for the other power supply in case of failure of the other power supply.

Generally, within the server enclosure 100, the server blades 108 share a common cooling subsystem (110) and a common power subsystem (114).

The server blades 108 also include respective temperature sensors 118 for detecting temperatures in the server blades 108. Each sever blade 108 can have one or multiple temperature sensors. Although not depicted, there may also be temperature sensors outside the server blades. Moreover, the server enclosure 100 can also include power sensors 119 to detect power consumption by different parts of the server enclosure 100. The power sensor 119 can be, for example, a current sensor.

The server enclosure 100 further includes a controller 118 that performs management tasks with respect to the components of the server enclosure 100. The controller 118 is able to communicate with the server blades 108, cooling subsystem 110, power subsystem 114, temperature sensors 118, and power servers 119 over one or more internal buses of the server enclosure 100.

The controller 118 includes an administrator 120, which can be a software module (or collection of software modules) executable on one or more central processing units (CPUs) 122 that is (are) connected to memory 124. The administrator 120 can handle thermal or power events within the server enclosure 100, in accordance with some embodiments.

The controller 118 (and more specifically the administrator 120) is able to monitor power consumption by the server blades 108 (using the power sensors 119, for example), monitor fan speeds, detect for failure of components within the power subsystem 114, and monitor temperature measurements taken by the temperature sensors 118 provided at various locations of the server enclosure 100. In response to a thermal or power event detected by the administrator 120, the administrator 120 accesses a policy (or policies) 125 maintained in the memory 124 to perform responsive actions.

The policy 125 maintained by the administrator 120 factors in power consumptions of the server blades 108 and fans 112 in making adjustments of operation of one or more of the server blades 108 and speeds of one or more of the fans 112. According to the policy 125, the administrator 120 can initially set the fans to provide reduced outputs (less than maximum outputs) to provide headroom to allow for the fans outputs to be increased. Moreover, by keeping the initial speeds of the fans at a lower level, more power of the power subsystem 114 can be made available for operation of the server blades 108, since the power subsystem 114 has a finite amount of power that has to be shared by the server blades 108 and the fans 112 (along with other components of the server enclosure 100).

Note that the finite amount of power of the power subsystem can be the maximum amount of power that can be produced by one of plural redundant power supplies (e.g., power supplies 116A, 116B).

The administrator 120 is also able to monitor advertisements of the server blades 108 regarding how much power is needed by the server blades 108. Therefore, before the administrator 120 allows a server blade 108 to turn on, the administrator 120 can determine whether sufficient power exists to satisfy what the server blade has advertised. If insufficient power is present, then the administrator 120 can prevent the server blade 108 from turning on, or alternatively, the administrator 120 can reduce power consumption elsewhere in the server enclosure 100 to provide additional power to allow the server blade 108 to turn on.

The administrator 120 can also monitor the percentage of the fan speed that has been used. This allows the administrator 120 to determine at any given time how much additional available cooling capacity exists for different parts of the server enclosure 100.

The policy 125 can also specify that the total power consumed by the server blades 108, fans 112, and other components of the server enclosure 100 should not exceed the maximum capacity of one of the power supplies 11 6A and 11 6B (assuming that the power subsystem 114 includes just two power supplies). This is to ensure that if one of the power supplies 116A and 116B should fail, the other power supply can take over, and the server enclosure 100 can continue to operate. A similar policy can be provided in a power subsystem that has more than two power supplies, with one of such power supplies designated as the failover power supply.

In accordance with some embodiments, at least some of the server blades 108 are capable of supporting capping. Capping refers to specifying some upper power level above which the server blade 108 will not cross. In some implementations, there are two types of capping: (1) thermal capping and (2) electrical capping. Electrical capping specifies a power cap (e.g. in terms of watts or amperage) that the server blade will not exceed. Thermal capping refers to an aggregate power value averaged over some time duration that is useful for thermal planning. Thus, over a given time duration, the server blade that is subject to thermal capping will not have an aggregate power value that exceeds some predefined threshold. The cap is indicated by a cap setting, which can be stored as a value in a storage element (e.g., register, buffer, etc.) of a server blade.

Some of the server blades 108 may not have capping capabilities. The administrator 120 is able to determine which of the server blades has capping capabilities, and which of the server blades do not. The administrator 120 can make this determination by submitting a request for the capping capability of each server blade 108. The administrator 120 can also request the capping mode (thermal capping mode or electrical capping mode) of the server blade. Moreover, the administrator 120 can request the current cap setting (e.g., power consumption cap).

One technique that can be used by the administrator 120 to reduce power consumption by a server blade in response to a power event or a thermal event is to reduce the current cap setting of one or more server blades. In response to a reduced cap setting, a server blade will automatically reduce power consumption, such as by performing clock throttling at the server, or scheduling less tasks to be performed by the server blade. Clock throttling refers either to reducing the frequency of a clock that is provided to components of the server blade, or reducing the duty cycle of the clock provided to such components. Reducing the duty cycle of a clock means that the ratio of the active period of the clock to the inactive period of the clock is reduced.

Alternatively, instead of adjusting the cap setting of a server blade, the administrator 120, through the controller 118, can adjust the value of one or more input pins of processors on the server blades 108. For example, one such input pin can be an input pin that can indicate that the processor is to be in an active state or a low power state. A lower power state refers to a reduced activity state (or off state) in which power consumption of the processor is reduced. An active state refers to a state in which the processor is allowed to operate at full capacity if desired.

Other techniques of reducing or increasing power consumption of a server blade can be performed in other implementations. Power consumption of a server blade is reduced by setting a lower cap setting, or setting the input pin(s) of processor(s) on the server blade to cause the processor(s) to enter a low power state. Increasing power consumption of a server blade refers to increasing the cap setting, or setting another state of the input pin(s) of the processor(s) on the server blade to cause the processor(s) to enter an active state.

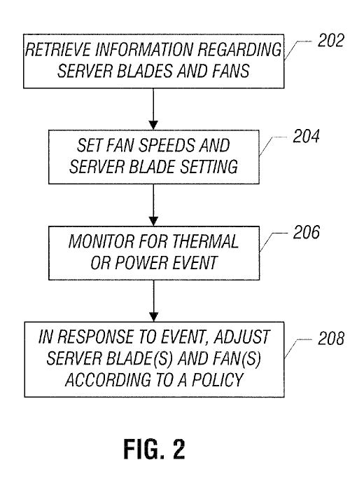

FIG. 2 shows a flow diagram of a general process according to an embodiment. Initially, the administrator 120 retrieves (at 202) information regarding the server blades and fans. In some implementations, the retrieval of information regarding the server blades can include retrieving capping capabilities, capping mode, and current cap settings of the server blades. The information retrieved for the fans includes the percentage of fan speed that is being used by each of the fans.

Next, according to the policy (e.g., policy 125 in FIG. 1), the administrator 120 sets (at 204) fan speeds and server blade settings. Initially, the fan speeds of the fans of the cooling subsystem 110 (FIG. 1) can be set at less than maximum speeds of the fans, to provide additional headroom in case additional cooling is desirable. Also, the administrator 120 can specify different cap settings for the server blades depending on one or more various factors, such as workloads of the server blades.

Next, the administrator 120 monitors (at 206) for an event, which can be either a thermal event or a power event. A thermal event may be a temperature measured by a temperature sensor exceeding some threshold. The power event may be a power consumption of a component (e.g., server blade) exceeding some threshold.

In response to the thermal or power event, the administrator 120 adjusts the server blade(s) and/or fan(s) according to the policy 125. The policy 125 may specify that fans are to be maintained at low speeds, and that server blades are to be throttled in the event of the thermal or power event. Alternatively, the policy 125 can specify that the server blades are to be throttled only after the highest fan speeds are unable to reduce temperature levels adequately in the server enclosure 100.

In one specific example, a thermal event may be indicated by excessive temperature within a particular server blade (as detected by the temperature sensor 118 within the server blade). In this example, the administrator 120 can increase the speed of the fan that has been previously determined to directly affect the thermal characteristics of the server blade that has signaled the thermal event. A fan is considered to directly affect the thermal characteristics of the server blade if an increase in the fan speed results in a decrease in temperature of the server blade.

Alternatively, or additionally, in response to the thermal event from the particular sever blade, the administrator 120 can also increase the speed of fans previously determined to directly affect the thermal characteristics of server blades adjacent the particular server blade that signaled the thermal event.

Moreover, the administrator 120 can also signal throttling of the particular server blade and/or its neighbors to reduce temperature.

The policy 125 specifies that some maximum power consumption level should not be exceeded according to the adjustments of cooling device outputs and server blade operations. As noted above, the power subsystem 114 can be able to specify some maximum power output, such that the aggregate of power consumption by the cooling devices, server blades, and other components of the server enclosure 100 should not exceed this maximum power level. Note that the maximum power level can be the maximum power level of one of multiple redundant power supplies. Maintaining the aggregate power consumption within the server enclosure 100 to be less than this maximum power level of one of multiple redundant power supplies allows for a different power supply to take over provision of power in the server enclosure 100 in case another power supply fails.

Note that the policy 125 can be updated based on actual operation of the components of the server enclosure 100. Updating such policy 125 refers to training the policy 125 (or more specifically, the algorithm specified by the policy 125) to enhance efficiencies and operations of the server enclosure 100. For example, based on actual operations of the server enclosure 100, the administrator 128 may detect optimal balances of cooling device outputs and server blade operations under different conditions. The policy 125 can then be updated to reflect the possible different scenarios that can be faced by the server enclosure 100. When the administrator 120 subsequently detects one of such scenarios is present, the administrator 120 can then make adjustments of cooling device outputs and server blade operations accordingly.

Instructions of software described above (including administrator 120 of FIG. 1) are loaded for execution on a processor (such as one or more CPUs 122 in FIG. 1). The processor includes microprocessors, microcontrollers, processor modules or subsystems (including one or more microprocessors or microcontrollers), or other control or computing devices. A “processor” can refer to a single component or to plural components.

Data and instructions (of the software) are stored in respective storage devices, which are implemented as one or more computer-readable or computer-usable storage media. The storage media include different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; and optical media such as compact disks (CDs) or digital video disks (DVDs). Note that the instructions of the software discussed above can be provided on one computer-readable or computer-usable storage medium, or alternatively, can be provided on multiple computer-readable or computer-usable storage media distributed in a large system having possibly plural nodes. Such computer-readable or computer-usable storage medium or media is (are) considered to be part of an article (or article of manufacture). An article or article of manufacture can refer to any manufactured single component or multiple components.

In the foregoing description, numerous details are set forth to provide an understanding of the present invention. However, it will be understood by those skilled in the art that the present invention may be practiced without these details. While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. A method for use in an electronic device enclosure, comprising:
monitoring for an event in the electronic device enclosure that includes a plurality of electronic devices, wherein the event includes one of a thermal event and a power event; and
in response to the event,
adjust an output of a cooling device in the electronic device enclosure, and
adjust an operation of at least one of the electronic devices,
wherein adjusting the output of the cooling device and operation of the at least one of the electronic devices is according to a policy that considers power consumption of the cooling device and the electronic devices.

2. The method of claim 1, further comprising providing a cooling subsystem including a plurality of cooling devices that are shared by the plurality of electronic devices.

3. The method of claim 1, further comprising monitoring an output level of the cooling device, wherein adjusting the output of the cooling device and operation of at least one of the electronic devices is based further on the monitored output level of the cooling device.

4. The method of claim 1, further comprising:
determining power consumption of the cooling device and of the electronic devices, wherein adjusting the output of the cooling device and operation of at least one of the electronic devices is further based on the determined power consumption.

5. The method of claim 4, further comprising:
determining a maximum power output of a power supply subsystem, wherein adjusting the output of the cooling device and the operation of the at least one of the electronic devices is further according to the determined maximum power output of the power subsystem.

6. The method of claim 5, wherein the maximum power output of the power subsystem is the maximum power output of one of plural redundant power supplies in the power subsystem, wherein adjusting the output of the cooling device and the operation of the at least one of the electronic devices is further based on ensuring that one of the plural redundant power supplies can continue to provide power to the electronic device enclosure in case of failure of at least one other of the power supplies in the power subsystem.

7. The method of claim 1, further comprising:
initially setting the cooling device to provide an output at less than a maximum output of the cooling device to reduce power consumption and to allow for additional power availability to the electronic devices.

8. The method of claim 1, wherein adjusting the operation of the at least one of the electronic devices comprises adjusting a cap setting of the at least one of the electronic devices.

9. The method of claim 8, wherein adjusting the cap setting comprises adjusting an electrical cap setting.

10. The method of claim 8, wherein adjusting the cap setting comprises adjusting a thermal cap setting.

11. The method of claim 8, further comprising sending a request to the electronic devices to determine respective cap settings of the electronic devices.

12. The method of claim 1, wherein adjusting the operation of the at least one of the electronic devices comprises adjusting a state of an input to the at least one of the electronic devices to cause the at least one of the electronic devices to transition between an active state and a low power state.

13. The method of claim 1, further comprising updating the policy according to monitored operations of components in the electronic device enclosure.

14. The method of claim 1, wherein the electronic device enclosure includes multiple cooling devices, the method further comprising:
detecting failure of one of the cooling devices, wherein adjusting the output of the cooling device and operation of the at least one of the electronic devices is further based on detection of the fan failure.

15. The method of claim 1, wherein the electronic device enclosure comprises plural cooling devices corresponding to respective electronic devices, wherein the event includes a thermal event signaled by a temperature sensor in a particular one of the electronic devices, wherein adjusting the output of the cooling device comprises adjusting the output of at least one of the cooling devices corresponding to the particular electronic device and an electronic device adjacent the particular electronic device, and wherein adjusting the operation of the at least one of the electronic devices comprises adjusting the operation of at least one of the particular electronic device and an electronic device adjacent the particular electronic device.

16. An electronic device enclosure comprising:
a cooling device;
a plurality of electronic devices; and
a controller to:
monitor for an event in the electronic device enclosure, wherein the event includes one of a thermal event and a power event,
in response to the event,
adjust an output of the cooling device,
adjust an operation of at least one of the electronic devices,
wherein the controller adjusts the output of the cooling device and operation of the at least one of the electronic devices according to a policy that considers power consumption of the cooling device and the electronic devices.

17. The electronic device enclosure of claim 16, wherein the operation of the at least one of the electronic devices is adjusted by performing clock throttling at the at least one of the electronic devices.

18. An article comprising at least one computer-readable storage medium containing instructions that when executed cause a controller in an electronic device enclosure to:
store a policy that specifies how cooling devices and electronic devices in the electronic device enclosure are to be adjusted in response to an event that includes one of a thermal event and a power event, wherein the policy considers power consumption of the cooling device and the electronic devices;
monitor for a thermal event or power event in the electronic device enclosure; and
in response to the event,
adjust the cooling device and at least one of the electronic devices according to the policy.

19. The article of claim 18, wherein the instructions when executed cause the controller to further:
receive measurement information from temperature sensors and power sensors, wherein adjusting the cooling device and the at least one of the electronic devices is further based on the received measurement information.

20. The article of claim 18, wherein adjusting the at least one electronic device comprises changing a cap setting of the at least one electronic device, the cap setting indicating a maximum power consumption of the at least one electronic device.
